(19) United States
(12) Patent Application Publication
(10) Pub. No.: US 2025/0337389 A1
(43) Pub. Date: Oct. 30, 2025

(54) RESONANCE DEVICE

(71) Applicant: Murata Manufacturing Co., Ltd., Nagaokakyo-shi (JP)

(72) Inventors: Ryota KAWAI, Nagaokakyo-shi (JP); Ville KAAJAKARI, Nagaokakyo-shi (JP); Fumiya ENDOU, Nagaokakyo-shi (JP)

(21) Appl. No.: 19/259,239

(22) Filed: Jul. 3, 2025

Related U.S. Application Data
(63) Continuation of application No. PCT/JP2023/038783, filed on Oct. 26, 2023.

(30) Foreign Application Priority Data
Feb. 1, 2023 (JP) 2023-014180

(51) Int. Cl. H03H 9/17; H03H 9/125

(52) U.S. Cl. CPC H03H 9/17; H03H 9/125

(57) ABSTRACT

A resonance device including: a vibrator layer having a vibration portion including a plurality of vibration arms. The plurality of vibration arms have a piezoelectric layer, and first and second electrode layers. The resonance device also includes first and second cover layers. The plurality of vibration arms have at least one inside vibration arm and at least two outside vibration arms. Either the first cover layer or the second cover layer has a first external terminal and a second external terminal. In one of the inside vibration arm and the outside vibration arms, the first and second electrode layers are both electrically connected to the first external terminal. In the other of the inside vibration arm and the outside vibration arms, one of the first and second electrode layers is electrically connected to the first external terminal and the other is electrically connected to the second external terminal.

### CROSS REFERENCE TO RELATED APPLICATIONS

The present application is a continuation of International application No. PCT/JP2023/038783, filed Oct. 26, 2023, which claims priority to Japanese Patent Application No. 2023-014180, filed Feb. 1, 2023, the entire contents of each of which are incorporated herein by reference.

### TECHNICAL FIELD

The present disclosure relates to a resonance device.

### BACKGROUND ART

Resonance devices manufactured by using a micro electro mechanical systems (MEMS) technology are popular. For example, resonance devices with a three-terminal configuration in which a lower electrode is electrically connected to a ground terminal are disclosed in Patent Documents 1, 2, and 3.

Patent Document 1: International Publication No. 2016/159018

Patent Document 2: International Publication No. 2020/045503

Patent Document 3: International Publication No. 2019/111439

### SUMMARY OF THE DISCLOSURE

However, because the resonance devices of Patent Documents 1, 2, and 3 employ the three-terminal configuration, when the size of the resonance device is reduced, the area of each terminal becomes small, and the distance between the respective terminals also becomes short. This will cause a short circuit between the terminals or paste defect of solder. It will be conceivable that a floating electrode is employed as the ground terminal in order to deal with the above-described problem. However, in this case, the following problem will occur. A charge is accumulated in the floating electrode due to electromagnetic noise from the exterior and the pyroelectric effect attributed to temperature change. Thus, an electrostatic attractive force occurs and the frequency changes, impairing the reliability.

The present disclosure has been made in view of such circumstances, and an object of the present disclosure is to provide a resonance device having high reliability while having compatibility with size reduction.

A resonance device according to an aspect of the present disclosure includes: a vibrator layer having: a vibration portion including a plurality of vibration arms and a base portion; a holding portion configured to hold the vibration portion; and a holding arm that connects the vibration portion to the holding portion, the plurality of vibration arms having a piezoelectric layer, first electrode layer on a first main surface of the piezoelectric layer, and a second electrode layer on a second main surface of the piezoelectric layer opposite to the first main surface, a fixed end of each of the plurality of vibration arms being connected to the base portion, the plurality of vibration arms have at least one inside vibration arm and at least two outside vibration arms each respectively disposed on opposite outer sides of the inside vibration arm in a plan view of the vibrator layer, and the inside vibration arm and the outside vibration arms are configured to be capable of out-of-plane bending vibration with phases different from each other; a first cover layer on a side of the first electrode layer of the vibrator layer; and a second cover layer on a side of the second electrode layer of the vibrator layer; and a first external terminal and a second external terminal on either the first cover layer or the second cover layer on an opposite side thereof to a side facing the vibrator layer, wherein in one of the inside vibration arm and the outside vibration arms, the first electrode layer and the second electrode layer are both electrically connected to the first external terminal, and in the other of the inside vibration arm and the outside vibration arms, one of the first electrode layer and the second electrode layer is electrically connected to the first external terminal and the other of the first electrode layer and the second electrode layer is electrically connected to the second external terminal.

According to the above-described aspect, the upper electrode layers and the lower electrode layers of the plurality of vibration arms are electrically connected to either the first external terminal or the second external terminal. According to this configuration, by employing a two-terminal configuration concerning the external terminals, a resonance device compatible with size reduction can be provided. Further, employing the above-described configuration can provide a resonance device in which the frequency stability is improved compared with a configuration in which a floating electrode is employed as one of the upper electrode layer and the lower electrode layer.

According to the present disclosure, a resonance device having high reliability while having compatibility with size reduction can be provided.

### BRIEF DESCRIPTION OF THE DRAWINGS

FIG. 1 is a perspective view schematically depicting a resonance device according to a first embodiment.

FIG. 2 is an exploded perspective view schematically depicting a configuration of the resonance device according to the first embodiment.

FIG. 3 is a plan view depicting a configuration of a vibrator layer according to the first embodiment.

FIG. 4 is a plan view depicting a configuration of an upper cover layer according to the first embodiment.

FIG. 5 is a sectional view of the resonance device according to the first embodiment along line V-V in FIGS. 3 and 4.

FIG. 6 is a sectional view of the resonance device according to the first embodiment along line VI-VI in FIGS. 3 and 4.

FIG. 7 is a sectional view of the resonance device according to the first embodiment along line VII-VII in FIGS. 3 and 4.

FIG. 8 is a sectional view of the resonance device according to the first embodiment along line VIII-VIII in FIGS. 3 and 4.

FIG. 9 is a sectional view depicting a configuration of a vibration portion according to a modification of the first embodiment.

FIG. 10 is a plan view depicting a configuration of an upper cover layer according to a second embodiment.

FIG. 11 is a sectional view along line XI-XI in FIG. 10.

### DESCRIPTION OF THE PREFERRED EMBODIMENTS

Embodiments of the present disclosure are described below with reference to the drawings. The drawings of these embodiments are given as examples, and the dimensions and the shape of each part are schematic. The technical scope of the disclosure of the present application should not be interpreted as a scope limited to these embodiments.

### First Embodiment

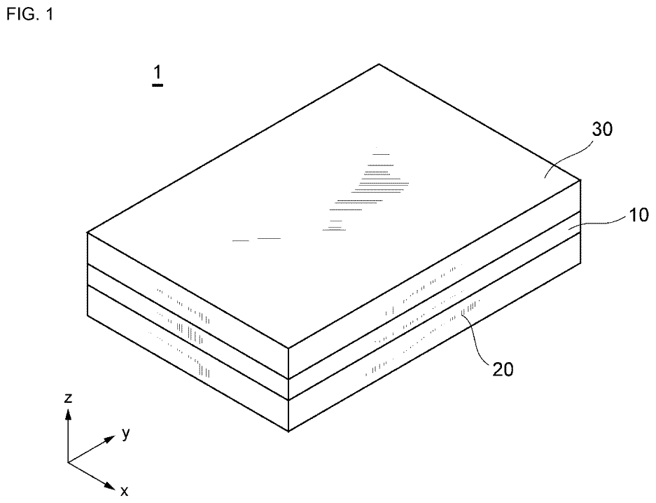

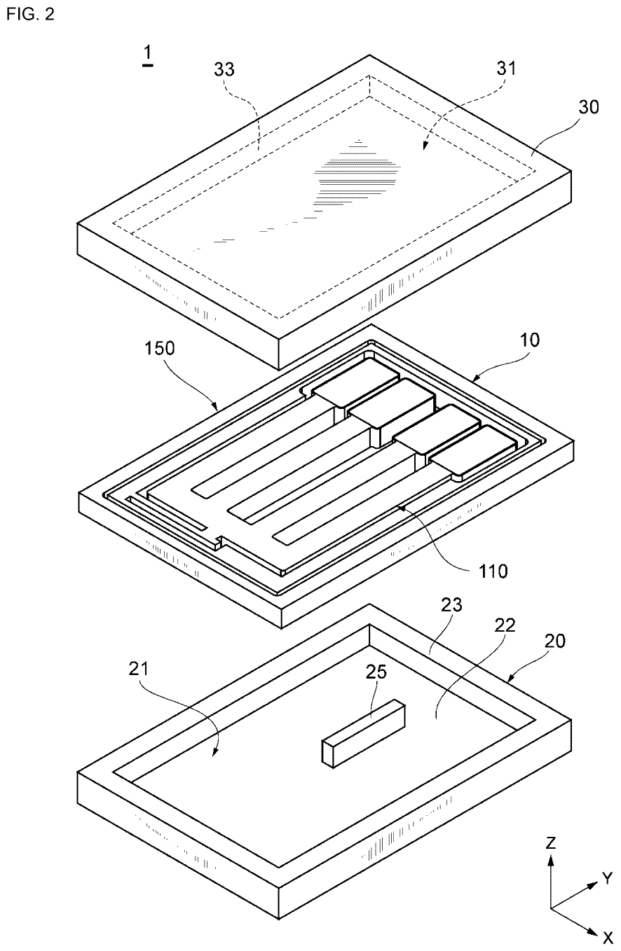

First, with reference to FIGS. 1 and 2, a schematic configuration of a resonance device in accordance with one embodiment is described. FIG. 1 is a perspective view schematically depicting the appearance of a resonance device 1 in the one embodiment. FIG. 2 is an exploded perspective view schematically depicting a structure of the resonance device 1 depicted in FIG. 1.

As depicted in FIGS. 1 and 2, the resonance device 1 includes a vibrator layer 10, and a lower cover layer 20 and an upper cover layer 30 that form a vibration space in which the vibrator layer 10 vibrates. That is, the resonance device 1 is formed by stacking the lower cover layer 20, the vibrator layer 10, and the upper cover layer 30 in that order.

In the following, each configuration of the resonance device 1 is described. The following description is given such that the side on which the upper cover layer 30 is disposed in the resonance device 1 is defined as the upper side (or front side) and the side on which the lower cover layer 20 is disposed is defined as the lower side (or back side).

The vibrator layer 10 is a MEMS vibrator manufactured by using a MEMS technology. The vibrator layer 10 and the upper cover layer 30 are joined with the interposition of a joining frame V2, to be described later, therebetween. Further, the vibrator layer 10 and the lower cover layer 20 are each formed by using a silicon (Si) substrate (hereinafter, referred to as “Si substrate”), and the Si substrates are joined to each other. The vibrator layer 10, the lower cover layer 20, and the upper cover layer 30 may each be formed by using a silicon-on-insulator (SOI) substrate obtained by stacking a silicon layer and a silicon oxide film.

The upper cover layer 30 extends into a flat plate shape along an XY-plane. A recessed portion 31 is formed on the side on which the vibrator layer 10 is disposed. The recessed portion 31 has a flat plate-shaped bottom portion and a sidewall 33 extending from the bottom portion toward the side on which the vibrator layer 10 is disposed. This can form part of the vibration space as a space in which the vibrator layer 10 vibrates. Moreover, a glass layer G1 is disposed in the recessed portion 31. The upper cover layer 30 may have a flat plate shape without having the recessed portion 31. Further, a getter layer for adsorbing an emitted gas may be formed on the surface on the side of the vibrator layer 10 in the recessed portion 31 of the upper cover layer 30. In plan view, the length of the upper cover layer 30 in an X-axis direction is, for example, approximately 320 μm, and the length in a Y-axis direction is, for example, approximately 600 μm.

The lower cover layer 20 has a bottom plate 22 that is disposed along the XY-plane and has a rectangular flat plate shape and a sidewall 23 extending from a rim portion of the bottom plate 22 in a Z-axis direction, that is, the stacking direction of the lower cover layer 20 and the vibrator layer 10. In the lower cover layer 20, a recessed portion 21 formed by the surface of the bottom plate 22 and the inner surface of the sidewall 23 is formed in the surface opposite to the vibrator layer 10. The recessed portion 21 forms part of the vibration space of the vibrator layer 10. The lower cover layer 20 may have a flat plate shape without having the recessed portion 21. Further, a getter layer for adsorbing an emitted gas may be formed on the surface on the side of the vibrator layer 10 in the recessed portion 21 of the lower cover layer 20.

The lower cover layer 20 includes a protrusion 25 formed on the surface of the bottom plate 22. A detailed configuration of the protrusion 25 is described later.

By joining the upper cover layer 30, the vibrator layer 10, and the lower cover layer 20, the vibration space of the vibrator layer 10 is sealed in an airtight manner and a vacuum state is kept. This vibration space may be filled with, for example, a gas such as an inert gas.

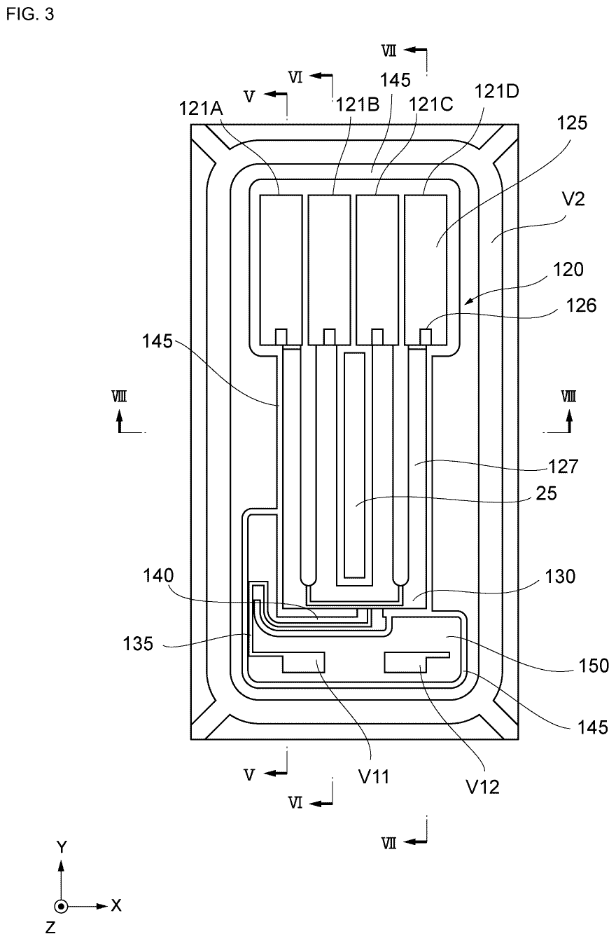

Next, with reference to FIG. 3, a schematic configuration of the vibrator layer in the resonance device in accordance with the one embodiment is described. FIG. 3 is a plan view schematically depicting a structure of the vibrator layer 10 depicted in FIG. 2.

As depicted in FIG. 3, the vibrator layer 10 is a MEMS vibrator manufactured by using a MEMS technology, and vibrates in the XY-plane in an orthogonal coordinate system in FIG. 3 such that an out-of-plane bending vibration mode is employed for principal vibration (hereinafter, also referred to as “main mode”). These vibrators are applied to, for example, timing devices, RF filters, duplexers, ultrasonic transducers, gyroscopic sensors, acceleration sensors, and the like. Further, the vibrators may be used for piezoelectric mirrors and piezoelectric gyroscopes having an actuator function, and piezoelectric microphones, ultrasonic vibration sensors, and the like having a pressure sensor function. Moreover, the vibrators may be applied to electrostatic MEMS elements, electromagnetically-driven MEMS elements, and piezo-resistance MEMS elements.

The vibrator layer 10 includes a vibration portion 120, a holding arm 140, and a holding portion 150.

The vibration portion 120 has a rectangular contour extending along the XY-plane in the orthogonal coordinate system in FIG. 3. The vibration portion 120 is disposed inside the joining frame V2. Isolation grooves 145 are formed at predetermined intervals between the vibration portion 120 and the holding portion 150. In the example of FIG. 3, the vibration portion 120 has four vibration arms 121A to 121D and a base portion 130. The vibration arms 121A to 121D and the holding arm 140 are each connected to the base portion 130. The vibration arms 121A to 121D have a tip portion 125 disposed on the tip side of the vibration arm 121A to 121D and an arm portion 127 disposed on the root side of the vibration arm 121A to 121D. The number of vibration arms is not limited to four. For example, the number of inside vibration arms is set to any number equal to or larger than one, and the number of outside vibration arms is set to any number equal to or larger than two as the number of vibration arms disposed on both outer sides of the inside vibration arms. In the present embodiment, the tip portions 125, the arm portions 127, and the base portion 130 are monolithically formed. The width of the tip portion 125 in the X-axis direction is, for example, approximately 42 μm. The width of the arm portion 127 in the X-axis direction is, for example, approximately 22 μm. The length of the vibration arms in the Y-axis direction as the total length of the tip portion 125 and the arm portion 127 is, for example, approximately 380 μm.

The vibration arms 121A, 121B, 121C, and 121D each extend in the Y-axis direction and are arranged in parallel at predetermined intervals in the X-axis direction in that order. One end of the vibration arm 121A is a fixed end connected to a front end portion of the base portion 130 to be described later. The other end of the vibration arm 121A is an open end disposed separately from the front end portion of the base portion 130. The vibration arm 121A includes a conductive portion 126 and a mass giving portion that are formed at the tip portion 125 on the open end side, and the arm portion 127 that extends from the fixed end and is connected to the mass giving portion. Similarly, the vibration arms 121B, 121C, and 121D each also include the mass giving portion and the arm portion 127.

The vibration arm 121 has a piezoelectric layer F2, an upper electrode layer E1 disposed on a first main surface of the piezoelectric layer F2 (on the side opposite to the upper cover layer 30), and a degenerate silicon layer F5 (a lower electrode layer E2) disposed on a second main surface of the piezoelectric layer F2 (on the side opposite to the lower cover layer 20).

The conductive portion 126 penetrates a frequency adjustment film F4, a protective film F1, the upper electrode layer E1, and the piezoelectric layer F2 at the tip portion 125, and is disposed to reach the lower electrode layer E2. By the conductive portion 126, the upper electrode layer E1 and the lower electrode layer E2 are electrically connected at the tip portion 125.

The mass giving portions have a mass giving film on each surface thereof. Therefore, the weight per unit length (hereinafter, also referred to as simply “weight”) of the mass giving portion is heavier than the weight of each of the arm portions. This can improve vibration characteristics while reducing the size of the vibration portion 120. Further, the mass giving films each have not only the function of increasing the weight of the tip portion 125 of the vibration arm 121A to the vibration arm 121D but also a function of adjusting the resonant frequency of the vibration arm 121A to 121D through removal of part of the mass giving film, that is, a function as a so-called frequency adjustment film.

When the vibrator layer 10 is viewed in plan view from the upper side (hereinafter, referred to as simply “in plan view”), the mass giving portions each have a substantially rectangular shape, and have a rounded curve shape, for example, a so-called round shape, at four corners. Similarly, the arm portions 127 each have a substantially rectangular shape and have a round shape near the fixed end connected to the base portion 130 and near a connected portion connected to a respective one of the mass giving portions. However, the shape of each of the mass giving portions and the arm portions 127 is not limited to the example of the present embodiment. For example, the shape of each of the mass giving portions and the arm portions 127 may be a substantially trapezoidal shape in plan view.

The base portion 130 has the front end portion, a rear end portion, a left end portion, and a right end portion in plan view. As described above, the fixed end of each of the vibration arms 121A to 121D is connected to the front end portion. The holding arm 140 to be described later is connected to the rear end portion.

The holding arm 140 connects the vibration portion 120 to the holding portion 150. The holding arm 140 extends in a Y-axis negative direction from the rear end portion of the base portion 130, and extends in an X-axis negative direction to be connected to the holding portion 150. Further, a connection portion 135 is disposed on the holding arm 140. The vibration arms 121 are electrically connected to a connection electrode V11 of the holding portion 150 to be described later by the connection portion 135.

The holding portion 150 is configured to hold the vibration portion 120. The holding portion 150 is disposed to surround the vibration portion 120 in plan view. Specifically, the holding portion 150 is configured to allow the vibration arms 121A to 121D to vibrate. Moreover, the connection electrodes V11 and V12 are disposed at the holding portion 150. The electrodes of the vibration arms 121 are electrically connected to external terminals T1 and T2 disposed on the upper cover layer 30 by the connection electrodes V11 and V12.

The holding portion 150 is only required to be disposed at at least part of the periphery of the vibration portion 120, and is not limited to the frame shape. For example, the holding portion 150 is only required to be disposed around the vibration portion 120 at such a degree as to be capable of holding the vibration portion 120 and joining to the upper cover layer 30 and the lower cover layer 20.

The protrusion 25 protrudes into the vibration space from the recessed portion 21 of the lower cover layer 20. The protrusion 25 is disposed between the arm portion 127 of the vibration arm 121B and the arm portion 127 of the vibration arm 121C in plan view. The protrusion 25 extends in the Y-axis direction in parallel to the arm portions 127, and is formed in a prism shape. The length of the protrusion 25 in the Y-axis direction is approximately 240 μm, and the length in the X-axis direction is approximately 15 μm. The number of protrusions 25 is not limited to one, and may be two or more. As described above, the protrusion 25 is disposed between the vibration arm 121B and the vibration arm 121C, and protrudes from the bottom plate 22 of the recessed portion 21. This can enhance the rigidity of the lower cover layer 20, and makes it possible to suppress bending of the vibrator layer 10 formed over the lower cover layer 20 and the occurrence of warpage of the lower cover layer 20.

The isolation groove 145 is configured to surround the vibration portion 120 and the holding arm 140 in plan view as depicted in FIG. 3. Further, the isolation groove 145 is configured to surround the connection electrodes V11 and V12 disposed at the holding portion 150 in plan view. Due to the provision of the isolation groove 145 in the above-described manner, the vibration portion 120 and the holding arm 140 are isolated from the holding portion 150. Moreover, the connection electrodes V11 and V12 are isolated from the joining frame V2 of the holding portion 150. Specifically, the isolation groove 145 is a groove that extends through the vibrator layer 10 from the front surface to the back surface. The isolation groove 145 is formed in a predetermined region in the holding portion 150, and has a substantially rectangular frame shape in plan view.

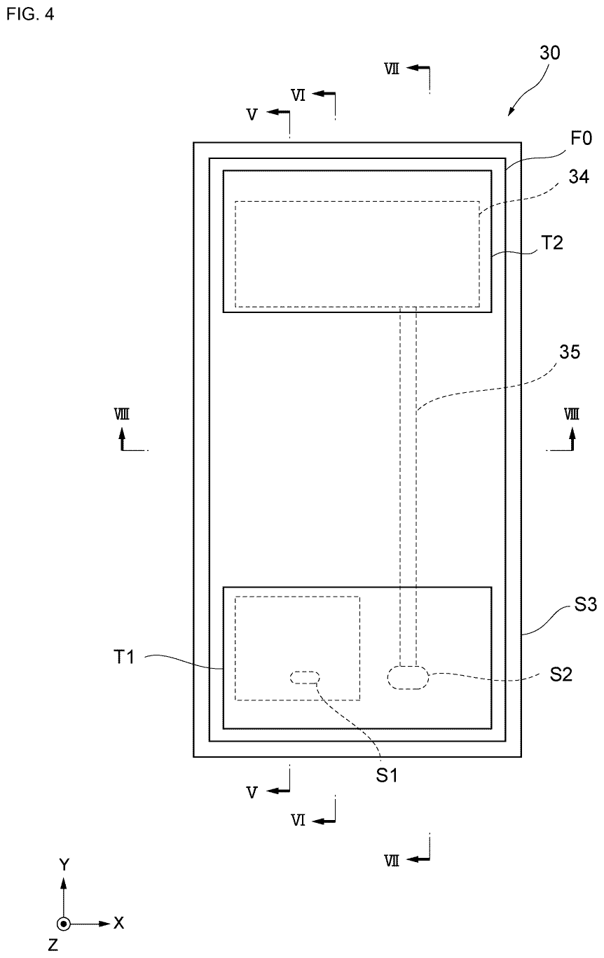

Next, a structure of the upper cover layer is described with reference to FIG. 4. FIG. 4 is a plan view of the upper cover layer 30 depicted in FIGS. 1 and 2.

The upper cover layer 30 is provided with the external terminals T1 and T2 on the opposite side to the side on which the vibrator layer 10 is disposed. Multilayer electrodes 34 are disposed inside the external terminals T1 and T2. Further, the upper cover layer 30 has silicon layers S1, S2, and S3. As depicted in FIG. 4, the external terminal T1 and the silicon layer S1 are electrically connected through the multilayer electrode 34. Similarly, the external terminal T2 and the silicon layer S2 are electrically connected through the multilayer electrode 34 and a connection wiring line 35 extending in the Y-axis negative direction from the multilayer electrode 34. The silicon layer S3 is disposed at a peripheral portion of the upper cover layer 30, and joins the vibrator layer 10 and the upper cover layer 30 with the joining frame V2 interposed therebetween.

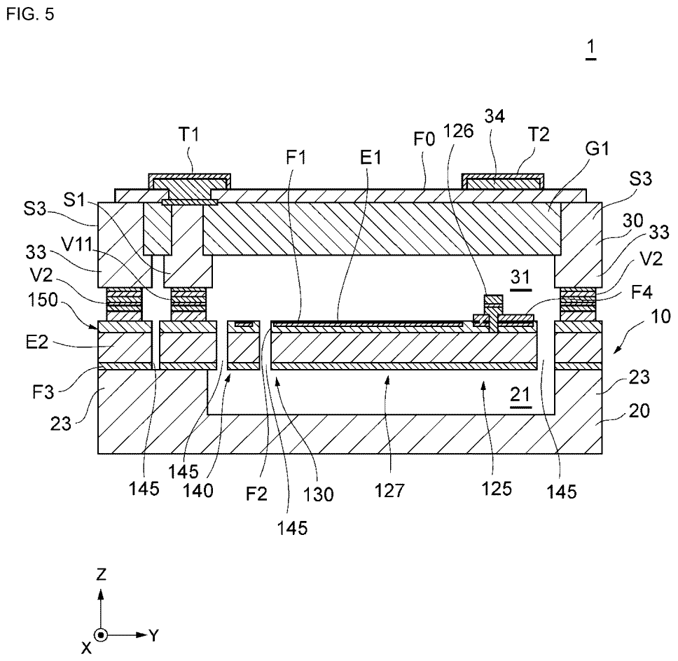

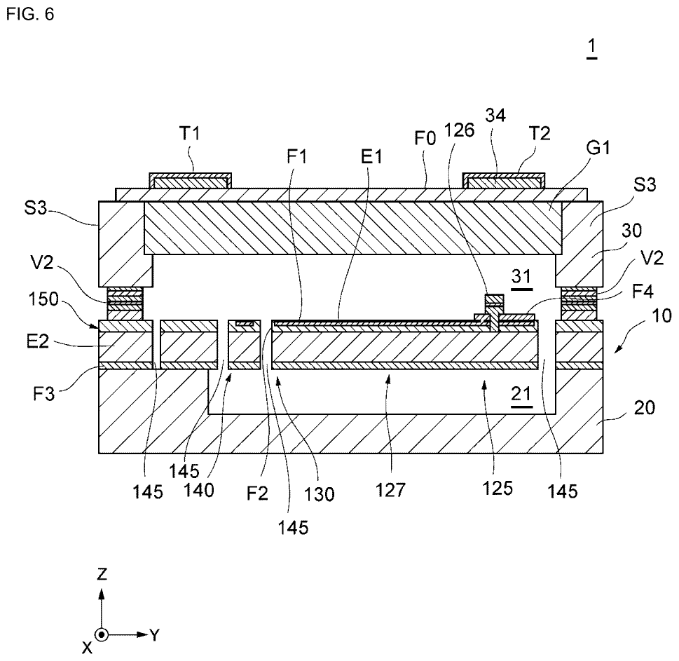

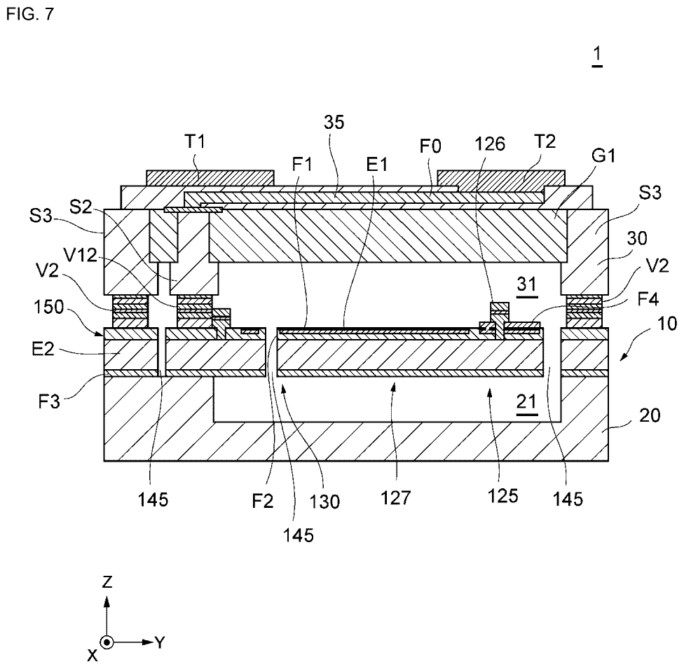

Next, with reference to FIGS. 5, 6, and 7, a multilayer structure and operation of the resonance device in accordance with the one embodiment are described. FIG. 5 is a sectional view along line V-V in FIGS. 3 and 4. FIG. 6 is a sectional view along line VI-VI in FIGS. 3 and 4. FIG. 7 is a sectional view along line VII-VII in FIGS. 3 and 4.

As depicted in FIG. 5, in the resonance device 1, the holding portion 150 of the vibrator layer 10 is joined onto the sidewall 23 of the lower cover layer 20. Moreover, the holding portion 150 of the vibrator layer 10 is joined to the sidewall 33 of the upper cover layer 30, formed of the silicon layer S3. The vibrator layer 10 is held between the lower cover layer 20 and the upper cover layer 30 in this manner, and the vibration space in which the vibration portion 120 vibrates is formed by the lower cover layer 20, the upper cover layer 30, and the holding portion 150 of the vibrator layer 10.

The vibration portion 120, the holding arm 140, and the holding portion 150 in the vibrator layer 10 are monolithically formed by the same process. In the vibrator layer 10, the lower electrode layer E2 is laminated on a silicon oxide layer F3 in contact with the lower cover layer 20. The piezoelectric layer F2 is laminated on the lower electrode layer E2 to cover the lower electrode layer E2, and the upper electrode layer E1 is laminated on the piezoelectric layer F2. The protective film F1 is laminated on the upper electrode layer E1 to cover the upper electrode layer E1. At the tip portions 125 of the vibration portion 120, further, the frequency adjustment films F4 are each laminated on the protective film F1. The outer shape of each of the vibration portion 120, the holding arm 140, and the holding portion 150 is formed by executing removal processing and patterning by, for example, dry etching for the multilayer body composed of the above-described silicon oxide layer F3, lower electrode layer E2, piezoelectric layer F2, upper electrode layer E1, protective film F1, and the like.

The lower electrode layer E2 is formed of, for example, a degenerate n-type silicon (Si) semiconductor with a thickness of approximately 6 μm, and can contain phosphorus (P), arsenic (As), antimony (Sb), or the like as an n-type dopant. The resistance value of the degenerate silicon (Si) used for the lower electrode layer E2 is, for example, smaller than 1.6 mΩ·cm, and preferably equal to or smaller than 1.2 mΩ·cm. Moreover, on the lower surface of the lower electrode layer E2, the silicon oxide layer F3 is formed as an example of a temperature characteristics correction layer. This can improve temperature characteristics.

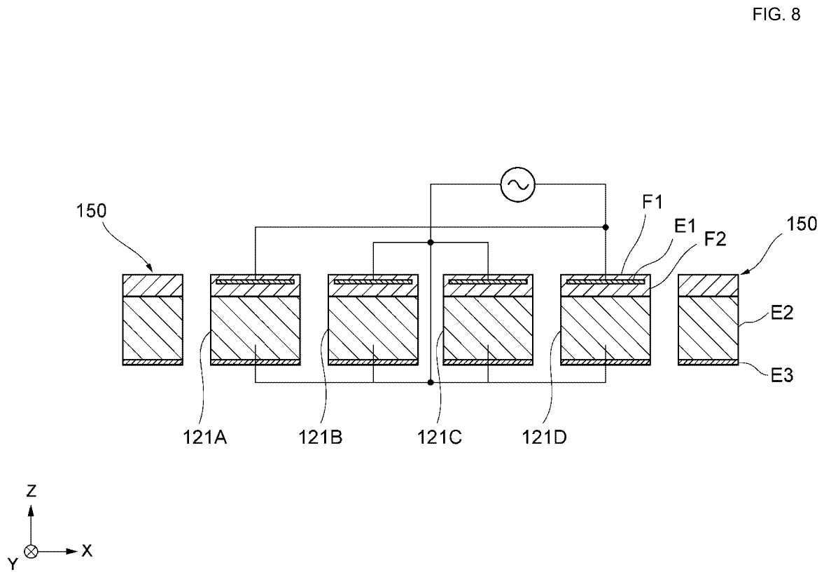

As depicted in FIGS. 3 and 5, the upper electrode layer E1 is disconnected between the tip portion 125 and the arm portion 127 in the vibration arms 121A and 121D. Further, as depicted in FIG. 6, the upper electrode layer E1 is connected between the tip portion 125 and the arm portion 127 in the vibration arms 121B and 121C. Due to this configuration, the upper electrode layer E1, the lower electrode layer E2, and the frequency adjustment film F4 of the inside vibration arms 121B and 121C are electrically short-circuited. Thus, electrical wiring of the vibrator layer 10 like that depicted in FIG. 8 is configured.

It is desirable that the protective film F1 be formed with a uniform thickness. The uniform thickness refers to a state in which variation in the thickness of the protective film F1 falls within ±20% from an average of the thickness.

The frequency adjustment film F4 is disposed on the surface on the side of the upper cover layer 30 in each of the tip portions 125 of the vibration arms 121A to 121D. The frequency of the vibrator layer 10 is adjusted by trimming treatment to remove part of each of the frequency adjustment films F4. In terms of the efficiency of the frequency adjustment, it is preferable that the frequency adjustment film F4 be formed of a material about which the rate of mass reduction by etching is higher than that of the protective film F1. The rate of mass reduction is expressed by the product of the etching rate and the density. The etching rate is the thickness removed per unit time. The magnitude relationship of the etching rate between the protective film F1 and the frequency adjustment film F4 may be any as long as the relationship of the rate of mass reduction therebetween is as described above. Further, in terms of efficiently increasing the weight of the tip portion 125, it is preferable that the frequency adjustment film F4 be formed of a material with a high specific gravity. For these reasons, the frequency adjustment film F4 is formed of, for example, a metal material such as molybdenum (Mo), tungsten (W), gold (Au), platinum (Pt), nickel (Ni), aluminum (Al), or titanium (Ti).

Part of the upper surface of each of the frequency adjustment films F4 is removed by the trimming treatment in a step of adjusting the frequency. The trimming treatment for the frequency adjustment film F4 can be executed by, for example, dry etching with irradiation with an argon (Ar) ion beam.

The connection electrodes V11 and V12 are formed on the protective film F1 of the holding portion 150. As depicted in FIG. 5, the silicon layer S1 is connected onto the connection electrode V11. As depicted in FIG. 7, the silicon layer S2 is connected onto the connection electrode V12. By these connections, the external terminal T1, the silicon layer S1, and the connection electrode V11 are electrically connected, and the external terminal T2, the silicon layer S2, and the connection electrode V12 are electrically connected.

The joining frame V2 is formed between the sidewall 33 of the upper cover layer 30 and the holding portion 150. The upper cover layer 30 and the vibrator layer 10 are joined by this joining frame V2. The joining frame V2 is formed in a frame shape to surround the vibration portion 120, the holding arm 140, and the connection electrodes V11 and V12. That is, the joining frame V2 is formed in a closed ring shape that surrounds the vibration portion 120 in the XY-plane in such a manner as to seal, in an airtight manner, the vibration space of the vibrator layer 10 in a vacuum state.

The joining frame V2 has electrical conductivity, and is formed of, for example, a metal film obtained by stacking an aluminum (Al) film, a germanium (Ge) film, and an aluminum (Al) film in that order and performing eutectic bonding of these films. The joining frame V2 may be formed by a combination of films selected as appropriate from gold (Au), tin (Sn), copper (Cu), titanium (Ti), silicon (Si), and the like. Further, the joining frame V2 may contain a metal compound such as titanium nitride (TiN) or tantalum nitride (TaN) between films in order to improve the adhesion.

At the holding portion 150, the isolation groove 145 is formed to extend from the protective film F1 formed on the front surface to the silicon oxide layer F3. Moreover, the isolation groove 145 electrically isolates the connection electrodes V11 and V12 and the joining frame V2 from each other. Due to this configuration, because the isolation groove 145 is formed to surround the connection electrodes V11 and V12 disposed at the holding portion 150 in plan view as described above, the exterior of the vibrator layer 10 and the vibration portion 120 are isolated by the isolation groove 145. Thus, a conduction path that reaches the vibration portion 120 from the exterior of the vibrator layer 10 via the holding portion 150 is interrupted before joining. Therefore, noise propagation to the vibration portion 120 through the holding portion 150 can be suppressed, and, for example, the resonant frequency can be adjusted with high accuracy at the time of frequency adjustment. Moreover, due to the electrical separation between the vibrator layer 10 and the periphery of the vibrator layer 10 by the isolation groove 145, parasitic capacitance at the time of substrate mounting by flip-chip bonding or the like can be reduced.

Next, the electrical wiring of the vibrator layer 10 is described with reference to FIG. 8. FIG. 8 is a sectional view along line VIII-VIII in FIGS. 3 and 4.

As depicted in FIG. 8, the holding portion 150 is electrically separated from the vibration arms 121A to 121D. Further, the upper electrode layers E1 of the outside vibration arms 121A and 121D are electrically connected to the external terminal T1. The upper electrode layers E1 of the inside vibration arms 121B and 121C are electrically connected to the external terminal T2. The lower electrode layers E2 of the vibration arms 121A to 121D are electrically connected to the external terminal T2. This allows the external terminals to have a two-terminal configuration. Moreover, compared with a configuration in which a floating electrode is employed as the lower electrode layer E2 and two terminals are employed, the resonance device 1 is less susceptible to a pyroelectric charge and noise from the exterior, and the frequency stability of the resonance device 1 can be improved.

In the present embodiment, the upper electrode layer E1 and the lower electrode layer E2 of the inside vibration arms 121B and 121C are electrically connected. However, the electrical connection structure is not limited thereto. For example, the upper electrode layers E1 and the lower electrode layers E2 of the outside vibration arms 121A and 121D may be electrically connected to the external terminal T1, and the upper electrode layers E1 of the inside vibration arms 121B and 121C may be electrically connected to the external terminal T2. Further, the lower electrode layers E2 of the vibration arms 121A to 121D may be electrically connected to the external terminal T1. Moreover, the lower electrode layers E2 of the inside vibration arms 121B and 121C and the outside vibration arms 121A and 121D are all electrically connected to either the external terminal T1 or T2.

As described above, in the resonance device 1 according to the present embodiment, the upper electrode layers E1 of the outside vibration arms 121A and 121D are electrically connected to the external terminal T1, and the lower electrode layers E2 of the outside vibration arms 121A and 121D are electrically connected to the external terminal T2. Further, the upper electrode layers E1 and the lower electrode layers E2 of the inside vibration arms 121B and 121C are electrically connected to the external terminal T2. With this electrical wiring, the lower electrode layers E2 of the vibration arms 121A to 121D are electrically connected to the external terminal T2. Thus, the frequency stability improves compared with the configuration in which a floating electrode is employed as the lower electrode layer. In addition, by employing the two-terminal configuration concerning the external terminals, a reduction in the size of the resonance device can be achieved.

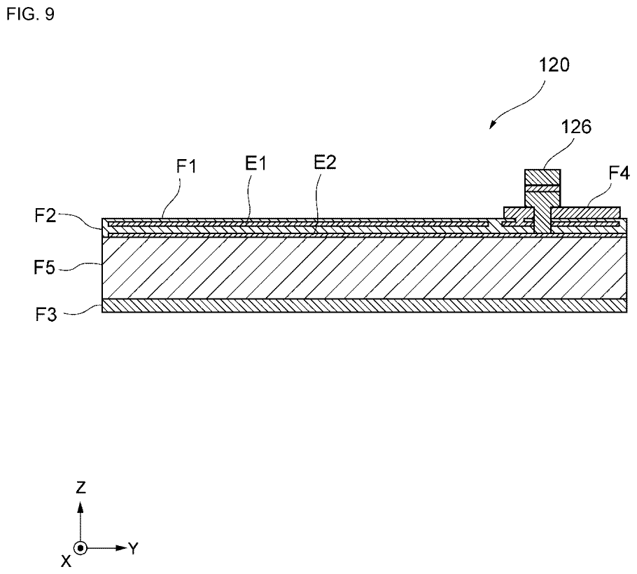

Although the lower electrode layer E2 has been described as one layer using degenerate silicon in the present embodiment, the lower electrode layer E2 is not limited thereto. For example, as depicted in FIG. 9, the degenerate silicon layer F5 may be disposed on the silicon oxide layer F3, and the lower electrode layer E2 formed of a metal layer may be separately disposed on the degenerate silicon layer F5.

A configuration of a resonance device according to another embodiment of the present disclosure is described below. In the following modification and embodiment, description is omitted concerning common matters with the above-described first embodiment and only a different point is described. In particular, mention is not made concerning every similar operation and effect by a similar configuration.

### Second Embodiment

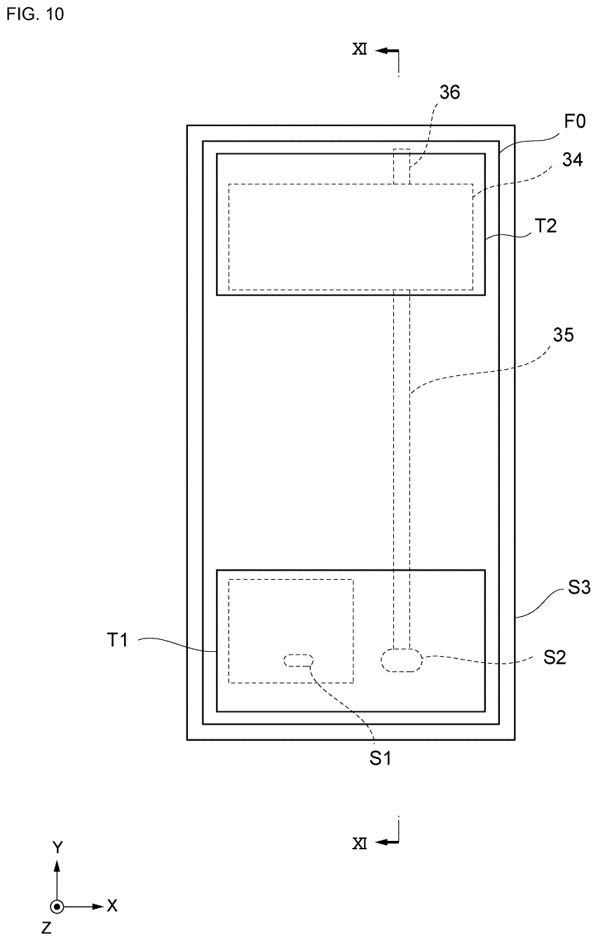

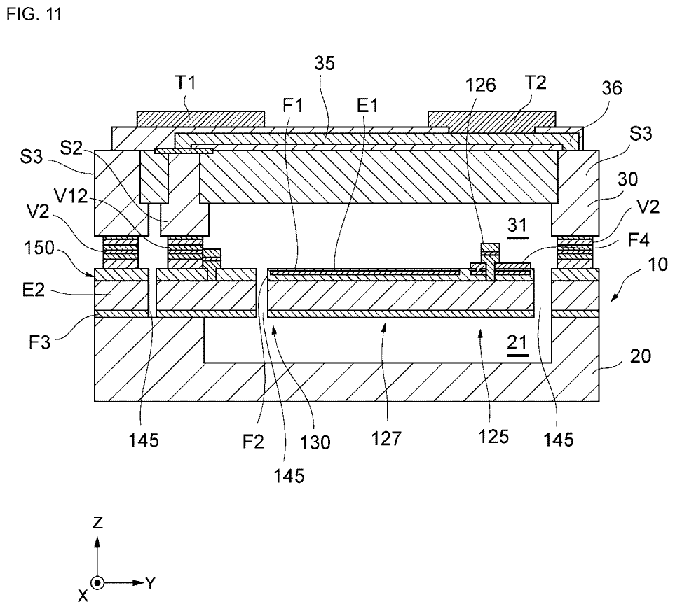

Next, with reference to FIGS. 10 and 11, a structure of a resonance device according to a second embodiment is described. FIG. 10 is a plan view schematically depicting an upper cover layer of the resonance device according to the second embodiment. FIG. 11 is a sectional view along line XI-XI in FIG. 10.

In the present embodiment, differently from the first embodiment, the upper cover layer 30 is provided with a connection wiring line 36 as depicted in FIG. 10. As depicted in FIGS. 10 and 11, the connection wiring line 36 is extended in a Y-axis positive direction from the multilayer electrode 34, and electrically connects the external terminal T2 and the silicon layer S3. According to this configuration, parasitic capacitance between the upper cover layer 30 and the lower cover layer 20 can be suppressed by connecting the silicon layer S3 of the upper cover layer 30 to the external terminal T2. Further, a frequency drift will occur when substrate mounting is performed by flip-chip bonding or the like. However, the frequency drift can be suppressed by connecting the silicon layer S3 to the external terminal T2 as in the present embodiment. Although the form in which the connection wiring line 36 is extended from the external terminal T2 has been described in the present embodiment, the connection wiring line 36 is not limited thereto. For example, the connection wiring line 36 may be extended from the external terminal T1.

Supplementary notes are made below concerning part or all of the embodiments of the present disclosure. The present disclosure is not limited to the following supplementary notes.

<1> As described above, according to an aspect of the present disclosure, there is provided a resonance device including: a vibrator layer having: a vibration portion including a plurality of vibration arms and a base portion; a holding portion configured to hold the vibration portion; and a holding arm that connects the vibration portion to the holding portion, the plurality of vibration arms having a piezoelectric layer, first electrode layer on a first main surface of the piezoelectric layer, and a second electrode layer on a second main surface of the piezoelectric layer opposite to the first main surface, a fixed end of each of the plurality of vibration arms being connected to the base portion, the plurality of vibration arms have at least one inside vibration arm and at least two outside vibration arms each respectively disposed on opposite outer sides of the inside vibration arm in a plan view of the vibrator layer, and the inside vibration arm and the outside vibration arms are configured to be capable of out-of-plane bending vibration with phases different from each other; a first cover layer on a side of the first electrode layer of the vibrator layer; and a second cover layer on a side of the second electrode layer of the vibrator layer; and a first external terminal and a second external terminal on either the first cover layer or the second cover layer on an opposite side thereof to a side facing the vibrator layer, wherein in one of the inside vibration arm and the outside vibration arms, the first electrode layer and the second electrode layer are both electrically connected to the first external terminal, and in the other of the inside vibration arm and the outside vibration arms, one of the first electrode layer and the second electrode layer is electrically connected to the first external terminal and the other of the first electrode layer and the second electrode layer is electrically connected to the second external terminal.

According to the above-described aspect, the lower electrode layers of the inside vibration arm and the outside vibration arms are electrically connected to the first external terminal or the second external terminal. This can provide the resonance device with a two-terminal configuration in which the frequency stability is improved compared with a configuration in which a floating electrode is employed as the lower electrode layer.

<2> As an aspect, the resonance device according to <1>, wherein the first cover layer has the first external terminal and the second external terminal, the holding portion surrounds the vibration portion in the plan view of the vibrator layer, and a first connection electrode electrically connected to the first external terminal, a second connection electrode electrically connected to the second external terminal, and a joining frame having a frame shape surrounding the vibration portion, the holding arm, the first connection electrode, and the second connection electrode in the plan view of the vibrator layer are each between the first cover layer and the holding portion.

According to the above-described aspect, parasitic capacitance that occurs between the upper cover layer and the lower cover layer at the time of substrate mounting can be reduced, and the frequency can be further stabilized.

<3> As an aspect, the resonance device according to <2>, wherein an isolation groove that electrically isolates the first connection electrode and the second connection electrode from the joining frame is located at the holding portion.

According to the above-described aspect, by isolating the vibrator layer from the periphery of the vibrator layer by the isolation groove, the parasitic capacitance can be reduced and the frequency can be further stabilized.

<4> As an aspect, the resonance device according to any one of <1> to <3>, wherein the second electrode layer comprises a degenerate silicon layer.

<5> As an aspect, the resonance device according to any one of <1> to <3>, wherein the second electrode layer is a metal layer, and the vibration portion further includes a silicon layer on an opposite side to a side of the second electrode layer on which the piezoelectric layer is disposed.

<6> As an aspect, the resonance device according to any one of <1> to <5>, wherein the second electrode layers of the inside vibration arm and the outside vibration arms are all electrically connected to either the first external terminal or the second external terminal.

The embodiments described above are those for facilitating understanding of the present disclosure, and are not those for interpreting the present disclosure in a limited manner. The present disclosure can be changed/modified without departing from the gist thereof, and equivalent thereof is also included in the present disclosure. That is, a configuration obtained by adding a design change to each embodiment as appropriate by those skilled in the art is also included in the scope of the present disclosure as long as the configuration has a feature of the present disclosure. For example, each element included in each embodiment and the arrangement, material, condition, shape, size, and the like thereof are not limited to that shown as an example, and can be changed as appropriate. Further, the respective elements included in each embodiment can be combined as long as the combination is technically possible, and a configuration obtained by combining them is also included in the scope of the present disclosure as long as the configuration includes a feature of the present disclosure.

### REFERENCE SIGNS LIST

1 resonance device
10 vibrator layer
20 lower cover layer
21 recessed portion
22 bottom plate
23 sidewall
25 protrusion
30 upper cover layer
31 recessed portion
33 sidewall
34 multilayer electrode
35, 36 connection wiring line
120 vibration portion
121A, 121B, 121C, 121D vibration arm
125 tip portion
126 conductive portion
127 arm portion
130 base portion
135 connection portion
140 holding arm
145 isolation groove
150 holding portion
S1, S2, S3 silicon layer
T1, T2 external terminal
V11, V12 connection electrode
V2 joining frame
E1 upper electrode layer
E2 lower electrode layer
F0 organic insulating film
F1 protective film
F2 piezoelectric layer
F3 silicon oxide layer
F4 frequency adjustment film
F5 degenerate silicon layer
G1 glass layer

1. A resonance device comprising:
a vibrator layer having:
a vibration portion including a plurality of vibration arms and a base portion;
a holding portion configured to hold the vibration portion; and
a holding arm that connects the vibration portion to the holding portion,
the plurality of vibration arms having a piezoelectric layer, first electrode layer on a first main surface of the piezoelectric layer, and a second electrode layer on a second main surface of the piezoelectric layer opposite to the first main surface,
a fixed end of each of the plurality of vibration arms being connected to the base portion,
the plurality of vibration arms have at least one inside vibration arm and at least two outside vibration arms each respectively disposed on opposite outer sides of the inside vibration arm in a plan view of the vibrator layer, and
the inside vibration arm and the outside vibration arms are configured to be capable of out-of-plane bending vibration with phases different from each other;
a first cover layer on a side of the first electrode layer of the vibrator layer; and
a second cover layer on a side of the second electrode layer of the vibrator layer; and
a first external terminal and a second external terminal on either the first cover layer or the second cover layer on an opposite side thereof to a side facing the vibrator layer, wherein
in one of the inside vibration arm and the outside vibration arms, the first electrode layer and the second electrode layer are both electrically connected to the first external terminal, and
in the other of the inside vibration arm and the outside vibration arms, one of the first electrode layer and the second electrode layer is electrically connected to the first external terminal and the other of the first electrode layer and the second electrode layer is electrically connected to the second external terminal.

2. The resonance device according to claim 1, wherein
the first cover layer has the first external terminal and the second external terminal,
the holding portion surrounds the vibration portion in the plan view of the vibrator layer, and
a first connection electrode electrically connected to the first external terminal, a second connection electrode electrically connected to the second external terminal, and a joining frame having a frame shape surrounding the vibration portion, the holding arm, the first connection electrode, and the second connection electrode in the plan view of the vibrator layer are each between the first cover layer and the holding portion.

3. The resonance device according to claim 2, wherein an isolation groove that electrically isolates the first connection electrode and the second connection electrode from the joining frame is located at the holding portion.

4. The resonance device according to claim 1, wherein the holding portion includes an isolation groove that surrounds the vibration portion and the holding arm in the plan view.

5. The resonance device according to claim 1, wherein the second electrode layer comprises a degenerate silicon layer.

6. The resonance device according to claim 1, wherein
the second electrode layer is a metal layer, and
the vibration portion further includes a silicon layer on an opposite side to a side of the second electrode layer on which the piezoelectric layer is disposed.

7. The resonance device according to claim 6, wherein the silicon layer is a degenerate silicon layer.

8. The resonance device according to claim 1, wherein the second electrode layers of the inside vibration arm and the outside vibration arms are all electrically connected to either the first external terminal or the second external terminal.

9. The resonance device according to claim 8, wherein
the first cover layer has the first external terminal and the second external terminal,
the holding portion surrounds the vibration portion in the plan view of the vibrator layer, and
a first connection electrode electrically connected to the first external terminal, a second connection electrode electrically connected to the second external terminal, and a joining frame having a frame shape surrounding the vibration portion, the holding arm, the first connection electrode, and the second connection electrode in the plan view of the vibrator layer are each between the first cover layer and the holding portion.

10. The resonance device according to claim 9, wherein an isolation groove that electrically isolates the first connection electrode and the second connection electrode from the joining frame is located at the holding portion.

11. The resonance device according to claim 8, wherein the holding portion includes an isolation groove that surrounds the vibration portion and the holding arm in the plan view.

12. The resonance device according to claim 8, wherein the second electrode layer comprises a degenerate silicon layer.

13. The resonance device according to claim 8, wherein
the second electrode layer is a metal layer, and
the vibration portion further includes a silicon layer on an opposite side to a side of the second electrode layer on which the piezoelectric layer is disposed.

14. The resonance device according to claim 13, wherein the silicon layer is a degenerate silicon layer.
